(19) United States
(12) Patent Application Publication
(10) Pub. No.: US 2026/0231630 A1
(43) Pub. Date: Aug. 6, 2026

(54) DISPLAY DEVICE, ELECTRONIC DEVICE INCLUDING THE DISPLAY DEVICE, AND METHOD FOR MANUFACTURING THE DISPLAY DEVICE

(71) Applicant: Samsung Display Co., Ltd., Yongin-si (KR)

(72) Inventors: Sung Kyun PARK, Yongin-si (KR); Yong-Hwan PARK, Yongin-si (KR); Min Jung LEE, Yongin-si (KR); Seong Jun LEE, Yongin-si (KR); Donghee CHOI, Yongin-si (KR)

(73) Assignee: Samsung Display Co., Ltd., Yongin-si (KR)

(21) Appl. No.: 19/384,732

(22) Filed: Nov. 10, 2025

(30) Foreign Application Priority Data
Feb. 3, 2025 (KR) 10-2025-0013371

(51) Int. Cl. H10K 59/124; H10K 59/12; H10K 59/40

(52) U.S. Cl. CPC H10K 59/124; H10K 59/1201; H10K 59/40

(57) ABSTRACT

A display device includes a substrate having a display area and a peripheral area adjacent to the display area, an emission layer above the display area, a pad portion on the upper surface of the peripheral area, a sensing layer above the emission layer, a protective layer above the sensing layer, and a planarization layer above the protective layer, the sensing layer including a sensing electrode, the protective layer including a first portion overlapping the planarization layer, a second portion and a third portion overlapping the peripheral area, the protective layer having a first opening in the peripheral area and overlapping the pad portion, the second portion surrounding a periphery of the first opening, the third portion including a portion surrounding a periphery of the second portion, and a thickness of the third portion being smaller than a thickness of the first portion and a thickness of the second portion.

### CROSS-REFERENCE TO RELATED APPLICATIONS

The present application claims priority to, and the benefit of, Korean Patent Application No. 10-2025-0013371, filed on Feb. 3, 2025, in the Korean Intellectual Property Office, the entire disclosure of which are incorporated herein by reference.

### BACKGROUND

### (a) Field

This disclosure relates to display devices, electronic devices including the display device, and method for manufacturing the display devices.

### (b) Description of the Related Art

A display device may be a device for displaying a screen, such as a Liquid Crystal Display (LCD), an Organic Light Emitting Diode (OLED) display, and so on. These display devices may be used in various electronic devices such as mobile phones, navigation systems, digital cameras, e-books, portable game consoles, or various terminals.

Recently, as the uses of display devices have diversified, various designs to improve the quality of display devices are being attempted.

A display device using a substrate having a flexible property may be designed to bend edges of a display panel where pad portions are located, thereby reducing dead space compared to a display device using a substrate having a rigid property. Reducing dead space can reduce the bezel width of the display device.

### SUMMARY

The example embodiments are intended to provide display devices and electronic devices with improved quality, and to provide economical and more efficient methods for manufacturing display devices without changing materials or adding processes to the protective layer disposed above a sensing layer.

According to some example embodiments, a display device includes a substrate having a display area and a peripheral area adjacent to the display area, an emission layer above the display area, a pad portion on the upper surface of the peripheral area, a sensing layer above the emission layer, a protective layer above the sensing layer, and a planarization layer above the protective layer, the sensing layer including a sensing electrode, the protective layer including a first portion overlapping the planarization layer, a second portion and a third portion overlapping the peripheral area, the protective layer having a first opening in the peripheral area and overlapping the pad portion, the second portion surrounding a periphery of the first opening, the third portion including a portion surrounding a periphery of the second portion, and a thickness of the third portion being smaller than a thickness of the first portion and a thickness of the second portion.

A difference between the thickness of the third portion and the thickness of each of the first portion and the second portion may be 1,000 Å to 5,000 Å.

An adhesion strength of the first portion may be greater than an adhesion strength of the third portion.

An adhesion strength of the second portion may be greater than the adhesion strength of the third portion.

The peripheral area may further include a bending area.

The protective layer may further have a second opening overlapping the bending area.

The protective layer may further include a fourth portion including portions on opposite sides of the second opening, and a thickness of the fourth portion may be greater than the thickness of the third portion.

The protective layer may further include a fifth portion between the first portion and the fourth portion, and a thickness of the fifth portion may be smaller than the thickness of the first portion and the thickness of the fourth portion.

At least one of the difference between a thickness of the fourth portion and the thickness of the third portion, or a difference between the thickness of the fourth portion and the thickness of the fifth portion may be 1,000 Å to 5,000 Å.

An adhesion strength of the fifth portion may be lower than the adhesion strength of the first portion.

The adhesion strength of the fourth portion may be greater than the adhesion strength of the third portion and an adhesion strength of the fifth portion.

According to some example embodiments, a method for manufacturing a display device includes forming a pad portion on an upper surface of a peripheral area of a substrate, forming an emission layer and a sensing electrode above a display area of the substrate, applying a protective material layer above the sensing electrode, positioning a photomask above the protective material layer and irradiating light through the photomask, developing the protective material layer to form a protective layer, and forming a planarization layer above the protective layer, the photomask including a first light-blocking portion overlapping the pad portion, a first light-transmitting portion overlapping the planarization layer, a second light-transmitting portion surrounding the first light-blocking portion, and a third light-transmitting portion surrounding the second light-transmitting portion, and a light transmittance in the first light-transmitting portion and the second light-transmitting portion being 90% or more (e.g., 90% to 99.9%).

A light transmittance in the third light-transmitting portion may be 20% to 70%.

The peripheral area may further include a bending area.

The photomask may further include a second light-blocking portion overlapping the bending area.

The photomask may further include a fourth light-transmitting portion including portions on opposite sides of the second light-blocking portion, and a light transmittance in the fourth light-transmitting portion may be 90% or more (e.g., 90% to 99.9%).

The photomask may further include a fifth light-transmitting portion between the first light-transmitting portion and the fourth light-transmitting portion, and a light transmittance in the fifth light-transmitting portion may be 20% to 70%.

The forming the planarization layer may include inkjet printing a monomer.

The irradiating light may include photo-curing the protective material layer using ultraviolet light as a light source.

According to some example embodiments, an electronic device includes a display module and a processor connected to the display module, the display module including a substrate having a display area and a peripheral area adjacent to the display area, an emission layer above the display area, a pad portion disposed on the upper surface of the peripheral area, a sensing layer above the layer, a protective layer above the sensing layer, and a planarization layer above the protective layer, the sensing layer includes a sensing electrode, the protective layer includes a first portion overlapping the planarization layer, a second portion and a third portion overlapping the peripheral area, the protective layer has a first opening in the peripheral area and overlapping the pad portion, the second portion surrounding a periphery of the first opening, the third portion includes a portion surrounding a periphery of the second portion, and a thickness of the third portion is smaller than a thickness of the first portion and a thickness of the second portion.

A difference between the thickness of the third portion and the thickness of each of the first portion and the second portion may be 1,000 Å to 5,000 Å.

According to some example embodiments, by applying differential exposure energy when forming a protective layer above a sensing layer, lifting of a layer at a pattern boundary during a development process can be prevented or reduced, and the adhesion strength of the protective layer can be adjusted by portion, thereby improving the quality of a display device.

### BRIEF DESCRIPTION OF THE DRAWINGS

FIG. 1 is a schematic perspective view of an electronic device according to some example embodiments.

FIG. 2 is a schematic perspective view of an electronic device according to some example embodiments.

FIG. 3 is a perspective view of a display device according to some example embodiments.

FIG. 4 is a schematic plan view of a display panel according to some example embodiments.

FIG. 5 is a cross-sectional view showing a part of a display device according to some example embodiments.

FIG. 6 is a cross-sectional view showing a method for manufacturing a display device according to some example embodiments.

FIG. 7 is a schematic plan view of a mask according to some example embodiments.

FIG. 8 is a cross-sectional view showing a display device after bending according to some example embodiments.

FIG. 9 is a cross-sectional view schematically showing a part of a display device according to some example embodiments.

FIG. 10 is a cross-sectional view showing a method for manufacturing a display device according to some example embodiments.

FIG. 11 is a schematic plan view of a mask according to some example embodiments.

FIG. 12 is a cross-sectional view showing the thickness difference in the second region and the third region of a protective layer according to some example embodiments.

FIG. 13 is a graph showing the thickness of a protective layer according to exposure energy according to some example embodiments.

FIG. 14 is a table showing the thickness of a protective layer according to exposure energy according to some example embodiments.

FIG. 15 is a table showing the adhesion strength of a protective layer according to different exposure energy according to some example embodiments.

FIG. 16 is a block diagram of an electronic device according to some example embodiments.

FIG. 17 are schematic diagrams of electronic devices according to various example embodiments.

### DETAILED DESCRIPTION

Hereinafter, various example embodiments of the present inventions will be described in detail with reference to the accompanying drawings so that those skilled in the art to which the present inventions pertain can easily practice it. The present inventions may be implemented in various different forms and are not limited to the example embodiments described herein.

To clearly explain the present inventions, parts irrelevant to the description have been omitted, and throughout the specification, the same or similar components will be designated by the same reference numerals.

Also, the size and thickness of each component shown in the drawings are arbitrarily shown for convenience of explanation, so the present inventions are not necessarily limited to what is shown. In the drawings, the thicknesses are enlarged to clearly express various layers and regions. And in the drawings, for convenience of explanation, the thicknesses of some layers and regions are exaggeratedly shown. In this disclosure, unless otherwise specified, thickness refers to a thickness measured in a direction perpendicular to the main surface of the substrate, or in the thickness direction of the substrate.

Also, when a part such as a layer, film, region, or plate is said to be “on” or “above” another part, this includes not only cases where it is “directly on” the other part, but also cases where there is another part in between. Conversely, when a part is said to be “directly on” another part, it means that there is no other part in between. Also, being “on” or “above” a reference part means being located above or below the reference part, and does not necessarily mean being located in the direction opposite to gravity.

Also, throughout the specification, when a part is said to “include” a component, this means that, unless there is a specific description to the contrary, it does not exclude other components but may include other components.

Also, throughout the specification, “in a plan view” means when the target part is viewed from above, and “in a cross-sectional view” means when a vertical cross-section of the target part is viewed from the side.

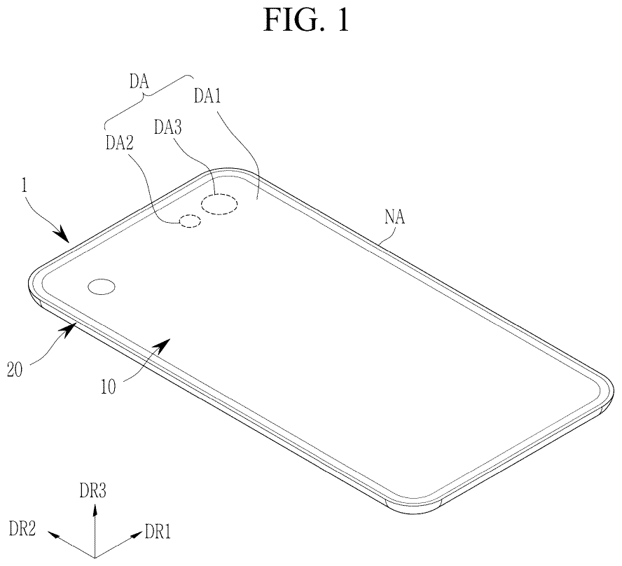

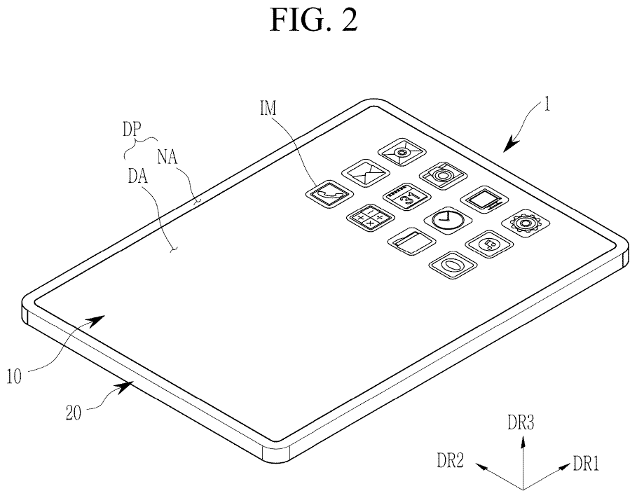

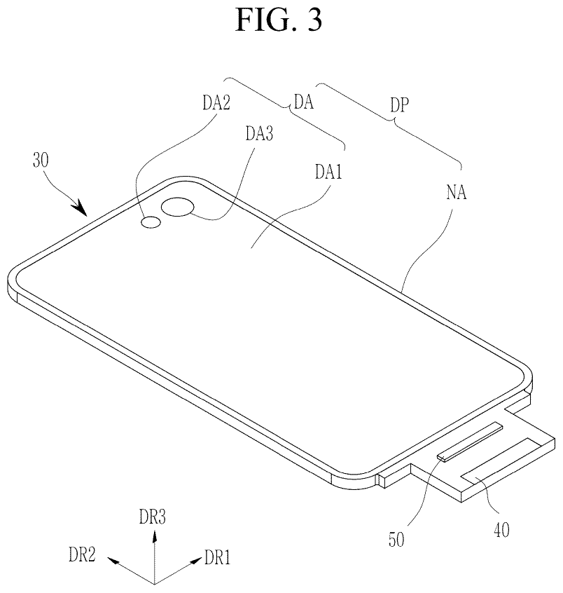

FIG. 1 and FIG. 2 are schematic perspective views of an electronic device according to some example embodiments. FIG. 3 is a perspective view of a display device according to some example embodiments.

Referring to FIG. 1 and FIG. 2, an electronic device 1 according to some example embodiments may include a display screen capable of displaying an image in a third direction DR3 corresponding to the front in a plane defined by a first direction DR1 and a second direction DR2. The electronic device 1 may be a device that includes displaying images as its main function, such as a smartphone, mobile phone, tablet, multimedia player, game console, monitor, and/or the like.

The electronic device 1 may display an image IM toward the first direction DR3. The image IM may include not only moving images but also still images. FIG. 2 shows multiple icons as an example of the image IM.

Referring to FIG. 1 to FIG. 3, an electronic device 1 according to some example embodiments may include a cover window 10, a housing 20, a display device 30, and/or the like.

The cover window 10 may include an insulating panel. For example, the cover window 10 may include glass, plastic, or a combination thereof. The front of the cover window 10 may define the front of the electronic device 1. The area of the cover window 10 corresponding to the display screen may be optically transparent. The cover window 10 may be positioned above the display device 30 to protect the display device 30 from external impacts, and/or the like, and may transmit images displayed by the display device 30. The cover window 10 may also be considered to be a component of the display device 30.

The housing 20 may be made of a material with high rigidity or relatively higher rigidity. For example, the housing 20 may include glass, plastic, or metal, or may include multiple frames and/or plates composed of a combination of these. The housing 20 may be combined with the cover window 10, and the combined housing 20 and cover window 10 may constitute the exterior of the electronic device 1 and provide an internal space of the electronic device 1. For example, the housing 20 may constitute the back and sides of the electronic device 1, and the cover window 10 may constitute the front of the electronic device 1. In the internal space defined by the cover window 10 and the housing 20, the display device 30, and/or the like, may be disposed, and the display device 30, and/or the like, may be protected from the external environment.

The display device 30 may display images and provide a display screen for the electronic device 1. The display device 30 may be an emissive display device such as an organic light emitting display device, an inorganic light emitting display device, a quantum dot light emitting display device, and/or the like.

The electronic device 1 may have various shapes. For example, the electronic device 1 may be a rectangle with rounded corners when viewed from the front, as shown in FIG. 1. In addition, the electronic device 1 may have the shape of a rectangle, square, other polygon, circle, ellipse, and/or the like.

The electronic device 1 and the display device 30 may each include a display area DA and a peripheral area NA. The display area DA and the peripheral area NA shown in FIG. 1 may correspond to the display area DA and the peripheral area NA of the display device 30 shown in FIG. 2. The display area DA may correspond to the display screen as an area where images are displayed. The peripheral area NA is an area where images are not displayed. The display area DA may occupy most of the area centered on the center of the front of the electronic device 1, and the peripheral area NA may surround the display area DA.

The display area DA may include a first display area DA1, a second display area DA2, and a third display area DA3. The second display area DA2 and the third display area DA3 may be areas where components such as a sensor and/or a camera are placed on the back to add various functions to the electronic device 1. The second display area DA2 and the third display area DA3 may correspond to a component area. The second display area DA2 and the third display area DA3 may be surrounded by the first display area DA1. Not only the first display area DA1, but also the second display area DA2 and the third display area DA3 may display images. The position and number of the second display area DA2 and the third display area DA3 may be variously changed.

To describe the display device 30 in more detail, the display device 30 may provide a display screen in the electronic device 1. The display device 30 may sense or capture the front of the electronic device 1. The display device 30 may have a planar shape similar to the electronic device 1.

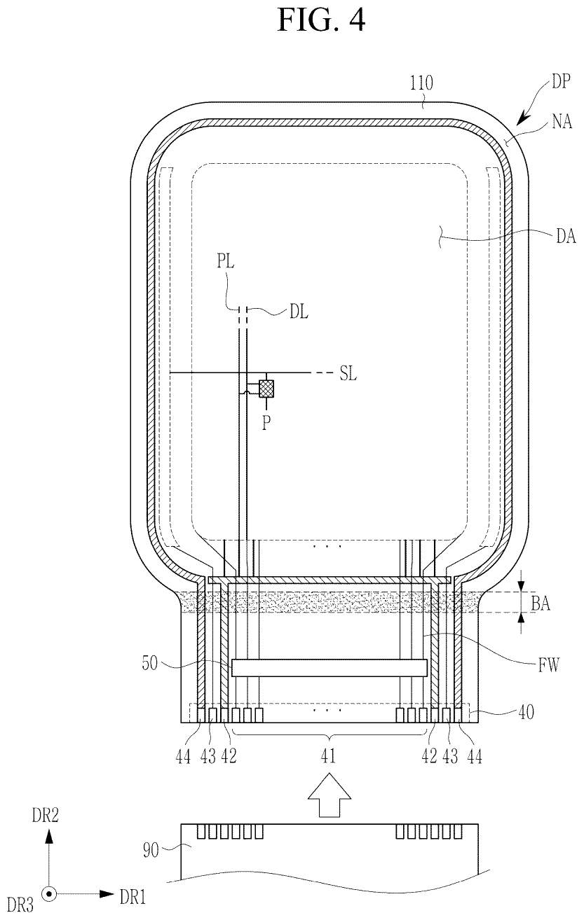

Hereinafter, the display device 30 and the display panel DP according to some example embodiments will be described with reference to FIG. 3 together with FIG. 4.

FIG. 4 is a schematic plan view of a display panel according to some example embodiments.

The display device 30 may include a display panel DP, a display driver 50, a touch driver (not shown), and a controller 90, and/or the like.

The display panel DP may be attached to the cover window 10 by an adhesive layer. The display panel DP may include a substrate 110. The display panel DP may include a display area DA and a peripheral area NA.

The display panel DP may include a display area DA where pixels for displaying images are arranged, and a peripheral area NA around the display area DA. The display area DA may include a first display area DA1, a second display area DA2, and a third display area DA3. Components such as a sensor or a camera may be placed on the back of the second display area DA2 and the third display area DA3, and the second display area DA2 and the third display area DA3 may correspond to a component area.

The display area DA may emit light from each pixel P in the first direction DR3. The display area DA includes pixels P connected to scan lines SL extending in a first direction (e.g., x-direction) and data lines DL and driving voltage lines PL extending in a second direction (e.g., y-direction) intersecting the first direction. The display area DA may include a plurality of pixels P. Each pixel P may emit, for example, red, green, blue, or white light (although the colors are not limited thereto). Each pixel P may include an organic light emitting diode including an organic emission layer, a quantum dot light emitting diode including a quantum dot emission layer, an inorganic light emitting diode including an inorganic semiconductor, and/or a micro light emitting diode.

The peripheral area NA may surround the display area DA. The peripheral area NA may be defined as the edge area of the main area MA of the display panel DP. In the peripheral area NA, circuits and/or signal lines for generating and/or transferring various signals applied to the display area DA may be arranged. For example, in the peripheral area NA, a gate driver that supplies gate signals to gate lines, and fan-out lines FW connecting the display driver 50 and the signal lines of the display area DA may be disposed.

A flexible area where bending, folding, rolling, and/or the like are possible may be included in an area extended from one side of the peripheral area NA. For example, the peripheral area NA may include a bending area BA. The bending area BA may be bent to overlap the display area DA in the thickness direction (the third direction DR3), thereby reducing the width of the peripheral area NA visible to the user.

The display driver 50 may be disposed in the peripheral area NA, and a pad portion 40 may be disposed at the edge of the peripheral area NA.

The pad portion 40 may include pads 41, 42, 43, and 44 for connecting with the controller 90. The pad portion 40 is arranged at one end of the substrate 110, and exposed rather than covered by an insulating layer to be electrically connected to the controller 90, such as a flexible printed circuit board (FPCB) or an IC chip.

The display driver 50 may output signals and/or voltages for driving the display panel DP. The display driver 50 may supply data voltages to the data lines. The display driver 50 may supply a power voltage to power lines, and gate control signals to the gate driver. The display driver 50 may be provided as an integrated circuit chip and may be mounted on the display panel DP. For example, the display driver 50 may be arranged in the peripheral area NA, and may overlap the display area DA in the thickness direction (the third direction DR3) when the display panel DP is bent.

The touch driver (not shown) may be provided as an integrated circuit chip and may be mounted on the controller 90. The touch driver may be electrically connected to a touch sensing unit included in the electronic device 1. The touch sensing unit may be provided in the display area DA of the display panel DP. The touch driver may supply an input signal (touch driving signal) to the sensing electrodes of the touch sensing unit, and may detect changes in capacitance between the sensing electrodes based on the output signal (touch sensing signal) from the sensing electrodes. For example, the touch driving signal may be a pulse signal having a predetermined (or, alternatively, desired, determined, or selected) frequency. The touch driver may calculate the presence of a touch and touch coordinates based on the change in capacitance between the sensing electrodes.

The controller 90 may convert image signals transferred from the outside into image data signals, and transfer the converted signals to the display driver 50 through the pad 41. Also, the display driver 50 may generate data signals, and the generated data signals may be transferred to the display area DA through the fan-out lines FW. Also, the controller 90 may receive a vertical synchronization signal, a horizontal synchronization signal, and a clock signal, generate a control signal for controlling the driving, and transfer it to each scan driver through the pad 43. The controller 90 may transfer a driving voltage ELVDD and a common voltage ELVSS to the driving voltage supply line and the common voltage supply line, respectively, through the pads 42 and 44.

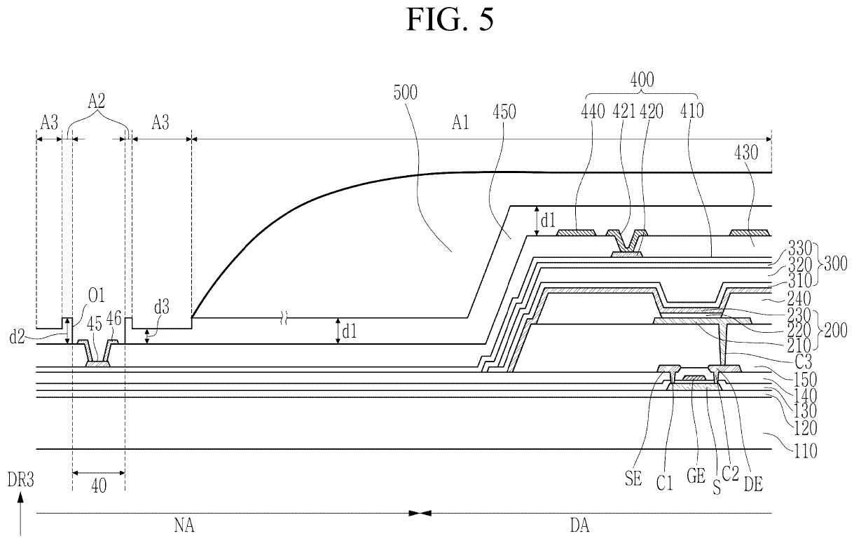

FIG. 5 is a cross-sectional view schematically showing a part of a display device according to some example embodiments. FIG. 5 shows a display panel DP in a case where there is no bending area BA.

As shown in FIG. 5, a display device according to some example embodiments may include a substrate 110, a buffer layer 120, a semiconductor layer S, a gate insulating layer 130, a gate electrode GE, an interlayer insulating layer 140, a source electrode SE, a drain electrode DE, a planarization insulating layer 150, a light emitting element 200, an encapsulation layer 300, a sensing layer 400, a protective layer 450, and a planarization layer 500, and/or the like.

The substrate 110 includes a display area DA and a peripheral area NA adjacent to the display area DA. A part of the peripheral area NA may be extended to one side. A pad portion 40 may be disposed on the upper surface of the extended part of the peripheral area NA.

The substrate 110 may include at least one among polystyrene, polyvinyl alcohol, polymethylmethacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, and/or the like.

The substrate 110 may be a rigid substrate or a flexible substrate capable of bending, folding, rolling, and/or the like. The substrate 110 may be a single layer or multiple layers. The substrate 110 may be formed by alternately (or sequentially) stacking at least one base layer including a polymer resin and at least one inorganic layer.

A buffer layer 120 may be disposed on the substrate 110. The buffer layer 120 may improve the characteristics of the semiconductor layer S by blocking impurities from the substrate 110 from penetrating into the semiconductor layer S. Also, the buffer layer 120 may planarize the upper surface over the substrate 110 to alleviate the stress of the semiconductor layer S formed above the buffer layer 120. The buffer layer 120 may have a single-layer or multi-layer structure. The buffer layer 120 may include at least one inorganic insulating material such as silicon nitride (SiNx), silicon oxide (SiOx), silicon oxynitride (SiOxNy), and/or the like.

A semiconductor layer S may be disposed above the buffer layer 120. The semiconductor layer S may include a channel region, and source and drain regions doped with an impurity. In some example embodiments, the semiconductor layer S may include a silicon semiconductor material. For example, the semiconductor layer S may include polysilicon or amorphous silicon. In some example embodiments, the semiconductor layer S may include an oxide semiconductor material. When the semiconductor layer S includes an oxide semiconductor material, it may include, for example, an oxide of at least one material selected from the group consisting of indium (In), gallium (Ga), tin (Sn), zirconium (Zr), hafnium (Hf), titanium (Ti), and zinc (Zn).

A gate insulating layer 130 is disposed on the substrate 110 to cover the semiconductor layer S and the buffer layer 120. The gate insulating layer 130 is formed as an inorganic insulating layer and may include silicon oxide (SiOx) or silicon nitride (SiNx), and/or the like.

A gate electrode GE may be disposed above the gate insulating layer 130. The gate electrode GE may include at least one metal material including aluminum (Al), molybdenum (Mo), copper (Cu), and/or the like. The gate electrode GE may overlap the channel region of the semiconductor layer S.

An interlayer insulating layer 140 may be disposed on the substrate 110 to cover the gate electrode GE and the gate insulating layer 130. The interlayer insulating layer 140 may include an inorganic insulating material including silicon oxide (SiOx) and/or silicon nitride (SiNx).

Openings C1 and C2 exposing the source region and the drain region of the semiconductor layer S may be formed in the interlayer insulating layer 140 and the gate insulating layer 130. A source electrode SE and a drain electrode DE disposed above the interlayer insulating layer 140 may be connected to the source region and the drain region of the semiconductor layer S, respectively, through the openings C1 and C2. Accordingly, the semiconductor layer S, the gate electrode GE, the source electrode SE, and the drain electrode DE may constitute a transistor.

A planarization insulating layer 150 may be disposed above the source electrode SE and the drain electrode DE. The planarization insulating layer 150 may be disposed on the substrate 110 to cover the source electrode SE, the drain electrode DE, and the interlayer insulating layer 140. The planarization insulating layer 150 may planarize the upper surface over the substrate 110 on which the transistor is formed. The planarization insulating layer 150 may include an organic insulating layer including one or more materials selected from the group consisting of polyimide, polyamide, acrylic resin, benzocyclobutene, and phenolic resin.

A light emitting element 200 and a bank 240 may be disposed above the planarization insulating layer 150. The light emitting element 200 may include a pixel electrode 210, an emission layer 220, and a common electrode 230.

The pixel electrode 210 may be formed in a single-layer structure including a transparent conductive oxide material and/or a metal material, or in a multi-layer structure including at least one of the transparent conductive oxide material and/or at least one of the metal material. The transparent conductive oxide material may include ITO (Indium Tin Oxide), poly-ITO, IZO (Indium Zinc Oxide), IGZO (Indium Gallium Zinc Oxide), and ITZO (Indium Tin Zinc Oxide), and/or the like, and the metal material may include silver (Ag), molybdenum (Mo), copper (Cu), gold (Au), and aluminum (Al), and/or the like.

An opening C3 exposing the drain electrode DE may be formed in the planarization insulating layer 150, so that the drain electrode DE and the pixel electrode 210 may be electrically connected through the opening C3.

The bank 240 may include an opening where a part of the upper surface of the pixel electrode 210 is exposed, and may partition the position where the emission layer 220 is formed so that the emission layer 220 can be formed on the exposed part of the upper surface of the pixel electrode 210. The bank 240 may include an organic insulating layer including one or more materials selected from the group consisting of polyimide, polyamide, acrylic resin, benzocyclobutene, and phenolic resin.

The emission layer 220 may be disposed above the display area DA. The emission layer 220 may be disposed within the opening partitioned by the bank 240. In FIG. 5, the emission layer 220 is shown as a single layer, but according some example embodiments, the emission layer 220 may further include at least one auxiliary layer such as an electron injection layer, an electron transport layer, a hole transport layer, and/or a hole injection layer, which may be disposed above or below the emission layer 220.

A common electrode 230 may be disposed above the bank 240 and the emission layer 220. The common electrode 230 may be formed as a transparent conductive layer and may include ITO (Indium Tin Oxide), IZO (Indium Zinc Oxide), IGZO (Indium Gallium Zinc Oxide), ITZO (Indium Tin Zinc Oxide), and/or the like.

An encapsulation layer 300 may be disposed above the common electrode 230. The encapsulation layer 300 may include a first inorganic layer 310, an organic layer 320, and a second inorganic layer 330. The first inorganic layer 310, the organic layer 320, and the second inorganic layer 330 are formed in the display area DA and a part of the peripheral area NA. The encapsulation layer 300 is for protecting the light emitting element 200 from moisture or oxygen from the outside, and one end of the first inorganic layer 310 and the second inorganic layer 330 may be positioned to directly contact the light emitting element 200. According to some example embodiments, the encapsulation layer 300 may include a structure where inorganic layers and organic layers are further stacked sequentially (e.g., alternatively).

A sensing layer 400 including sensing electrodes 420 and 440 may be disposed above the emission layer 220 and the encapsulation layer 300. The sensing layer 400 may sense contact in various ways and may be classified as a resistive type, a capacitive type, an electro-magnetic type, an optical type, and/or the like.

The sensing layer 400 may include a sensing buffer layer 410, an electrode connection part 421 disposed above the sensing buffer layer 410, a sensing insulating layer 430, a first sensing electrode 420, a second sensing electrode 440, and a protective layer 450.

The sensing buffer layer 410 may be disposed between the electrode connection part 421 and the encapsulation layer 300. The sensing buffer layer 410 may include inorganic materials such as LiF, and may insulate the sensing layer 400 from the encapsulation layer 300.

The sensing insulating layer 430 may include an opening exposing the upper surface of the first sensing electrode 420, and through the opening, the first sensing electrode 420 may be connected to the electrode connection part 421. In this case, the electrode connection part 421 may serve as a connection part connecting the patterned first sensing electrodes 420 in one direction.

The sensing insulating layer 430 may be disposed in the display area DA and the peripheral area NA. A pad electrode 46 formed in the pad portion 40 may be electrically connected to and directly contact a data conductive layer 45 exposed by an opening of the sensing insulating layer 430. According to some example embodiments, the pad electrode 46 may be electrically connected to and directly contact a gate conductive layer (not shown) formed in the same layer as the gate electrode GE.

The sensing insulating layer 430 may include at least one inorganic material and/or at least one organic material. The inorganic material may include at least one among silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. The organic material may include at least one among acrylic resin, methacrylic resin, polyisoprene, vinyl resin, epoxy resin, urethane resin, cellulose resin, or perylene resin.

A first sensing electrode 420 and a second sensing electrode 440 may be disposed above the sensing insulating layer 430. The first sensing electrode 420 and the second sensing electrode 440 may be a single layer or multi-layers including at least one conductive material with good conductivity (good conductivity may be a conductivity to transfer a signal through and/or to outside the material such that the signal maintains readability and/or fidelity).

According to some example embodiments, both the first sensing electrode 420 and the second sensing electrode 440 may be disposed above the sensing insulating layer 430 or below the sensing insulating layer 430. In this case, neighboring first sensing electrodes 420 or neighboring second sensing electrodes 440 may be electrically connected to each other through the electrode connection part 421. In some example embodiments, the first sensing electrode 420 and the second sensing electrode 440 may both serve as sensors, or neighboring first sensing electrode 420 and second sensing electrode 440 may together form a mutual capacitance sensor.

A protective layer 450 may be disposed above the sensing layer 400. The protective layer 450 may be disposed above the first sensing electrode 420 and the second sensing electrode 440. The protective layer 450 may protect the sensing electrodes 420, 440 by being positioned to cover the sensing insulating layer 430 disposed in the display area DA and the sensing insulating layer 430 of the peripheral area NA. The protective layer 450 may include at least one organic material, for example, polyimide.

A planarization layer 500 may be disposed above the protective layer 450. The planarization layer 500 is for improving the flatness of the upper part of the sensing layer 400. A cover window 10 is attached above the display panel, and a light-blocking layer may exist on the back of the cover window. In this case, the planarization layer 500 may planarize the display panel even at the part where it overlaps the light-blocking layer. The planarization layer 500 may overlap the display area DA and a part of the peripheral area NA. Therefore, in the display device, the upper surface of the display panel is flat or substantially flat in the part where light enters, allowing uniform light reflection. In the case where the planarization layer 500 is introduced, an image stain due to light reflection may be reduced compared to the case where the planarization layer 500 is not included.

The protective layer 450 may be formed by a photolithography process. A photosensitive material may be used as the material for the protective layer, and after development process, the photosensitive material may remain after being exposed to ultraviolet light. The protective layer 450 may have differences in adhesion strength to the upper layer and layer thickness depending on the degree of light irradiation during the process, that is, the exposure energy.

When the exposure energy for the protective layer 450 is relatively higher, e.g., at 50 mJ or more (e.g., 50 mJ to 1,000 mJ), the adhesion strength with the upper layer formed or attached above the protective layer 450 increases, and a remaining film rate of the protective layer 450 also increases, resulting in a thicker layer compared to when the exposure energy is relatively lower, e.g., at 50 mJ or less (e.g., 50 mJ to 1 mJ). When the exposure energy for the protective layer 450 is relatively higher, the remaining film rate is relatively higher, which can prevent or reduce the phenomenon of the layer lifting during the development process. Therefore, in a part of the upper surface of the protective layer 450 where relatively higher adhesion strength is desired, the adhesion strength can be increased by applying a relatively higher exposure energy. Also, to prevent or reduce layer lifting. particularly at the pattern boundary, which is vulnerable to layer lifting, a relatively higher exposure energy is applied to such a part, and as a result, the phenomenon of the protective layer 450 lifting during the development process can be prevented or reduced.

When the exposure energy for the protective layer 450 is relatively low, the adhesion strength with the upper layer decreases, and the remaining film rate also decreases, resulting in a thinner layer compared to when the exposure energy is relatively high. Therefore, in a part where lower adhesion strength is desired on the upper surface of the protective layer 450, the adhesion strength can be reduced by applying a relatively lower exposure energy.

Referring to FIG. 5, the protective layer 450 includes a first portion A1 overlapping the planarization layer 500, a second portion A2 and a third portion A3 overlapping the peripheral area NA. The protective layer 450 has a first opening O1 disposed in the peripheral area NA and overlapping the pad portion 40. Upper surfaces of the first portion A1, the second portion A2, and the third portion A3 of the protective layer 450 may contact different layers from each other, and different adhesion strengths and layer thicknesses may be desired for each portion of the protective layer 450. In this disclosure, unless otherwise specified, a thickness refers to a thickness measured in a direction perpendicular to the main surface of the substrate, or in the thickness direction of the substrate (e.g., the third direction DR3).

The first portion A1 may be disposed so that the upper surface of the first portion A1 may contact the planarization layer 500. If the adhesion strength between the first portion A1 of the protective layer 450 and the planarization layer 500 is low, they may delaminate, which can degrade the quality of the display device. Therefore, it is desirable that the first portion A1 has relatively higher adhesion strength with respect to the planarization layer 500. For this, higher exposure energy compared to other parts of the protective layer 450 is applied to the first portion A1, and accordingly, the adhesion strength of the first portion A1 respect to the planarization layer 500 may be increased.

The second portion A2 may be disposed surrounding the periphery of the first opening O1. The second portion A2 may correspond to a pattern boundary as it surrounds around the opening. At such a pattern boundary, film lifting may occur during the development process when insufficient exposure energy is applied. Therefore, by applying sufficient exposure to increase the remaining film rate, the layer lifting phenomenon can be prevented or reduced. Therefore, layer lifting phenomenon of the second portion A2 can be prevented or reduced by applying a higher exposure energy compared to other part of the protective layer.

The third portion A3 is disposed surrounding the periphery of the second portion A2. The upper surface of the third portion A3 may be disposed adjacent to a protective film in a subsequent process. The protective film may be used to prevent or reduce damage to the substrate or display device during the process, or to block contamination of the display device surface. A Polymer film such as polyethylene (PE) or polyethylene terephthalate (PET) film may be used as the protective film. The protective film is removed in a subsequent cell process. Since the protective film must be removed during the cell process, if the adhesion strength between the third portion A3 and the protective film is high, damage due to delamination in the panel may occur when the protective film is removed. In this case, display driving defect due to the delamination in the panel may occur when driving the display device. Therefore, the third portion A3 is desired to have lower adhesion strength respect to the protective film than other portion of the protective layer 450. By applying a relatively lower exposure energy to the third portion A3 compared to other portion of the protective layer 450, the adhesion strength of the third portion A3 with the protective film attached during the process may be decreased.

The first portion A1 and the second portion A2 may be formed with a higher exposure energy compared to the third portion A3. In the case of a negative type protective layer 450, as the exposure energy increases, the thickness of the layer increases, so the thickness d3 of the third portion A3 may be smaller than the thickness d1 of the first portion A1 and the thickness d2 of the second portion A2. The difference between the thickness d3 of the third portion A3 and the thickness d1 of the first portion A1 and the thickness d2 of the second portion A2 may be 1,000 Å or more (e.g., 1,000 Å to 5,000 Å).

The first portion A1 and the second portion A2 may be formed with a higher exposure energy compared to the third portion A3. As the exposure energy for the protective layer 450 increases, the adhesion strength to the upper layer above the protective layer 450 increases, so the adhesion strength of the first portion A1 may be greater than the adhesion strength of the third portion A3. The adhesion strength of the second portion A2 may be greater than the adhesion strength of the third portion A3.

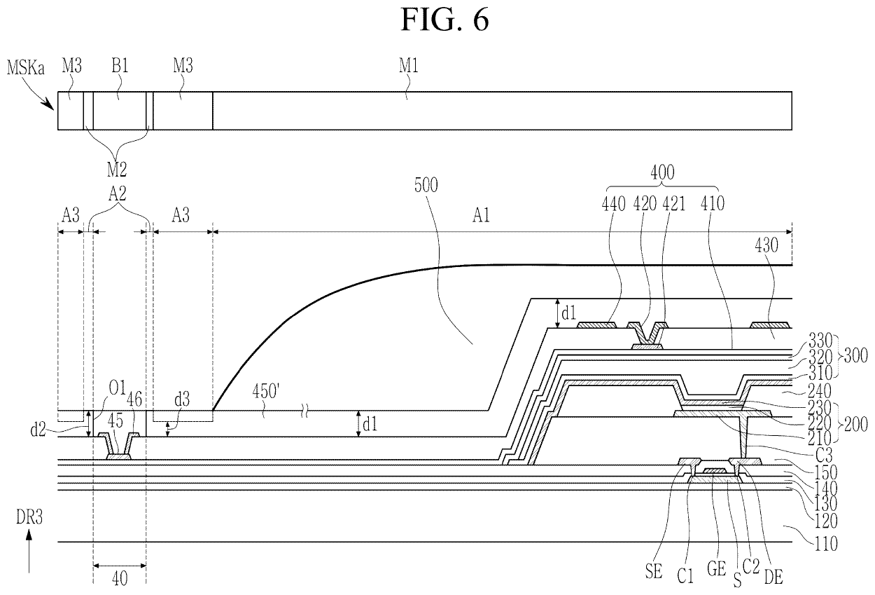

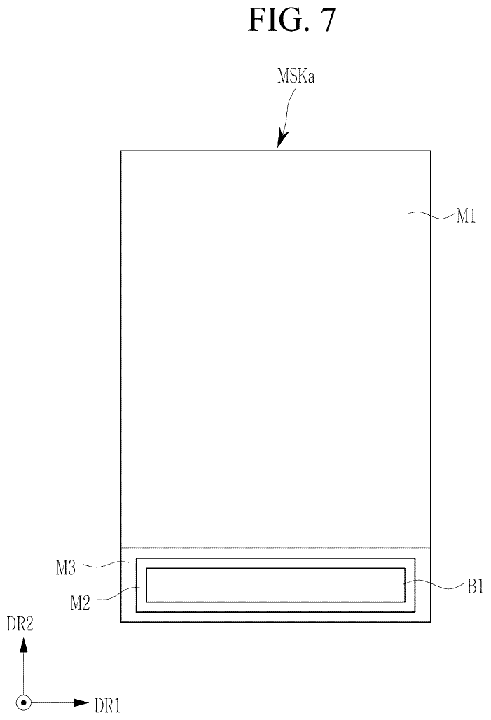

FIG. 6 is a cross-sectional view showing a method for manufacturing a display device according to some example embodiments, and shows a method for forming the protective layer 450 of the display device according to FIG. 5. FIG. 7 is a schematic plan view of a photomask MSKa according to some example embodiments. Hereinafter, a method for manufacturing a display device according to some example embodiments will be described with reference to FIGS. 6 and 7.

Referring to FIG. 6, a pad portion 40 is formed on the upper surface of the peripheral area NA of the substrate 110. An emission layer 220 and sensing electrodes 420, 440 are formed above the display area DA of the substrate 110. A protective material layer 450′ is applied above the sensing electrodes 420, 440. Using the photomask MSKa placed above the protective material layer 450′, light is exposed through the photomask MSKa. The exposing step may include photo-curing the protective material layer 450′ using ultraviolet light as a light source. After exposure, the protective material layer 450′ is developed to form a protective layer 450. After the step of forming the protective layer 450, g a planarization layer 500 may be formed above the protective layer 450. The step of forming the planarization layer 500 may include inkjet printing an organic material such as monomers.

Referring to FIGS. 6 and 7, the photomask MSKa includes a first light-blocking portion B1 overlapping the pad portion 40, a first light-transmitting portion M1 overlapping the display area, a second light-transmitting portion M2 surrounding the first light-blocking portion B1, and a third light-transmitting portion M3 surrounding the second light-transmitting portion M2. According to some example embodiments, the protective material layer 450′ may be a negative type photosensitive material with the characteristic that the part exposed to light remains after development. Therefore, in the part where light is blocked by the first light-blocking portion B1, the protective material layer 450′ does not remain (or is removed), so an opening may be formed. In the parts where light is irradiated by the first to third light-transmitting portions M1, M2 and M3, the protective layer 450 is formed, and the thickness of the protective layer 450 may be formed differently depending on the exposure energy. In a display device according to some example embodiments, the first opening O1 may be formed corresponding to the first light-blocking portion B1, the first portion A1 may be formed corresponding to the first light-transmitting portion M1, the second portion A2 may be formed corresponding to the second light-transmitting portion M2, and the third portion A3 may be formed corresponding to the third light-transmitting portion M3.

The light transmittance in the first light-transmitting portion M1 and the second light-transmitting portion M2 may be 90% or more (e.g., 90% to 99.9%). The first light-transmitting portion M1 and the second light-transmitting portion M2 may be full-tone masks where 90% or more (e.g., 90% to 99.9%) of light is transmitted. The first portion A1 formed corresponding to the first light-transmitting portion M1 may have higher adhesion strength, and the second portion A2 formed corresponding to the second light-transmitting portion M2 corresponds to a boundary part of the pattern, and therefore a certain exposure energy to prevent or reduce layer lifting phenomenon in the development process is beneficial. To this end the light transmittance in the first light-transmitting portion M1 and the second light-transmitting portion M2 is higher than the light transmittance in the third light-transmitting portion M3.

The light transmittance in the third light-transmitting portion M3 may be 20% to 70%. The third light-transmitting portion M3 may be a half-tone mask. The third light-transmitting portion M3 may be a slit mask or include a translucent part. A protective layer is attached on the third portion A3 formed corresponding to the third light-transmitting portion M3, and since the protective layer is removed in the subsequent process, the third portion A3 may have a relatively lower adhesion strength to prevent or reduce delamination. Therefore, by setting the transmittance of the third light-transmitting portion M3 to 20% to 70%, the exposure energy applied to the protective material layer 450′ in the part overlapping the third light-transmitting portion M3 can be lower than in the first light-transmitting portion M1 and the second light-transmitting portion M2.

In this way, by differentiating the transmittance of the photomask MSKa by part and applying differential exposure energy to the protective material layer 450′, the adhesion strength and thickness of the protective layer 450 can be controlled by part. By controlling the adhesion strength and thickness of the protective layer 450 by part, layer lifting phenomenon can be prevented or reduced during the development process, and deterioration of the quality of the display device can be prevented or reduced.

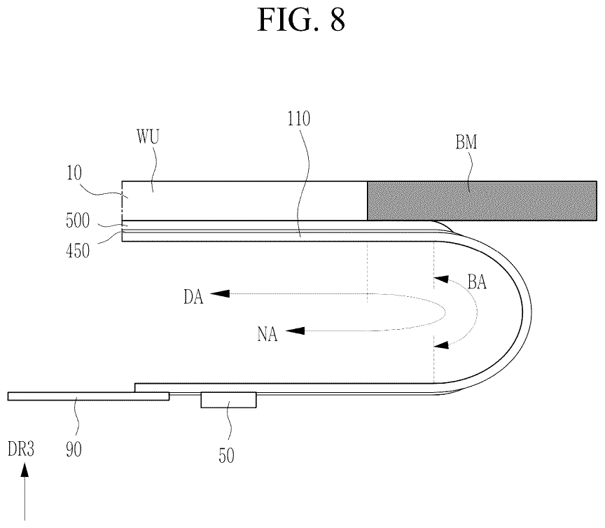

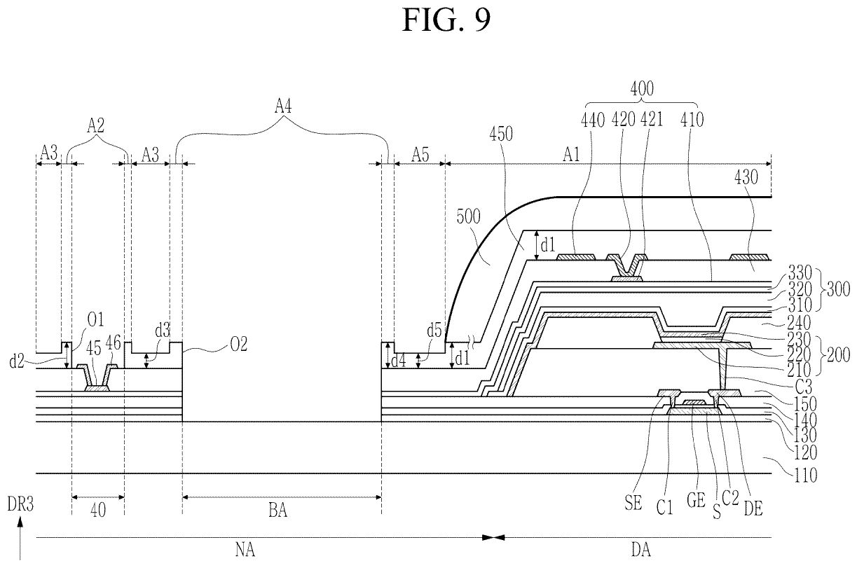

Hereinafter, a display device according to some example embodiments will be described with reference to FIGS. 8 and 9. FIGS. 8 and 9 show a display device with a bending area, where FIG. 8 is a cross-sectional view showing the display device after bending, and FIG. 9 is a cross-sectional view schematically showing a part of the display device.

According to FIG. 8, the display panel DP can be bent at the bending area BA. On the display panel DP, as explained with reference to FIG. 4, the display driver 50 and the controller 90 may be disposed on the peripheral area NA. As part of the peripheral area NA of the display panel DP is bent at the bending area BA as shown in FIG. 8, the area of the non-display area visible to the user can be dramatically reduced.

Meanwhile, in the process of bending the display panel DP, stress may be applied to the bending area BA. As explained with reference to FIG. 4, wires such as fan-out lines FW pass through the bending area BA, and there is a problem that the stress applied to the layers on the wires at the bending area BA may cause cracks in the wires or other damage/defects, increasing the risk of disconnection of the wires. A part of the protective layer 450 corresponding to the bending area BA of the display panel is patterned and removed. Referring to FIG. 9, the protective layer 450 may have a second opening O2 corresponding to the bending area BA.

Referring to FIG. 9, a semiconductor layer S, a light emitting element 200, and an encapsulation layer 300 may be disposed above the substrate 110. A sensing layer 400 may be disposed on the substrate 110, and a protective layer 450 may be disposed above the sensing layer 400. A planarization layer 500 may be disposed above the protective layer 450.

Referring to FIG. 8, a cover window 10 may be arranged above the planarization layer 500. The cover window 10 may include a window layer WU and a light-blocking part BM.

The window layer WU is above the display area DA, and a part of the window layer WU may extend to the peripheral area NA. A light-blocking part BM overlapping the peripheral area NA may be arranged on one side of the window layer WU. The light-blocking part BM may be provided as a separate structure, or may be provided by coating a light-blocking material on a part of the window layer WU. Since the peripheral area NA is a non-display area, a light-blocking part BM may be arranged to prevent or reduce an area not used for image display from being visible to the user.

The planarization layer 500 overlaps the display area DA and also overlaps a part of the light-blocking part BM of the cover window 10. Therefore, the upper surface of the display panel DP may be flat or substantially flat in the part where external light enters, and uniform light reflection may occur above the display device. In the case where the planarization layer 500 is introduced, stains visible in the displayed image due to light reflection may be reduced compared to the case where the planarization layer 500 is not applied.

FIG. 9 is a cross-sectional view schematically showing a part of a display device in the case where there is a bending area BA. FIG. 9 shows a display panel DP in the case where there is a bending area BA.

A display device according to some example embodiments may include a substrate 110, a buffer layer 120, a semiconductor layer S, a gate insulating layer 130, a gate electrode GE, an interlayer insulating layer 140, a source electrode SE, a drain electrode DE, a planarization insulating layer 150, a light emitting element 200, an encapsulation layer 300, a sensing layer 400, a protective layer 450, and a planarization layer 500.

The protective layer 450 may be formed by a photolithography process. A photosensitive material may be used as the material for the protective layer 450, and for example, such a material may remain after being exposed to ultraviolet light and development process. The protective layer 450 may have differences in adhesion strength to an upper layer and a layer thickness depending on the exposure energy during the process.

Referring to FIG. 9, the protective layer 450 may include a first portion A1 overlapping the planarization layer 500, a second portion A2 and a third portion A3 overlapping the peripheral area NA. The protective layer 450 may have a first opening O1 disposed in the peripheral area NA and overlapping the pad portion 40. Also, the protective layer 450 may further have a second opening O2 overlapping the bending area BA. The protective layer 450 may further include a fourth portion A4 having portions opposing each other with the second opening O2 therebetween, and may further include a fifth portion A5 disposed between the first portion A1 and the fourth portion A4. Layers contacting on the first portion A1 to the fifth portion A5 of the protective layer 450 may be different, and the adhesion strengths and layer thicknesses of the first portions A1 to the fifth portion A5 may be different.

The planarization layer 500 may be disposed adjacent to the upper surface of the first portion A1. Therefore, higher adhesion strength is desired to prevent or reduce delamination between the first portion A1 and the planarization layer 500. A relatively higher exposure energy may be applied to the first portion A1 compared to other parts of the protective layer 450, and as a result, the adhesion strength to the planarization layer 500 may be increased.

The second portion A2 may surround the periphery of the first opening O1. The second portion A2 may correspond to a pattern boundary as it surrounds around the opening. At such a pattern boundary, layer lifting may occur during the development stage when there is insufficient exposure energy. Therefore, by applying sufficient exposure energy to increase the remaining film rate, the layer lifting phenomenon can be prevented or reduced. Therefore, a relatively higher exposure energy may be applied to the second portion A2 compared to other parts of the protective layer, and as a result, layer lifting phenomenon can be reduced or prevented or reduced.

The fourth portion A4 may have portions disposed on opposite sides of the second opening O2. The fourth portion A4 may correspond to a pattern boundary as it is disposed at both boundaries of the opening. Like the second portion A2, layer lifting may occur during the development stage when there is insufficient exposure to light at the pattern boundary. Therefore, the fourth portion A4 may be formed by applying a relatively higher exposure energy compared to other parts.

The third portion A3 surrounds the periphery of the second portion A2. The fifth portion A5 may be disposed between the first portion A1 and the fourth portion A4. The upper surfaces of the third portion A3 and the fifth portion A5 may be disposed adjacent to a protective layer during the process. The protective layer may be removed during a subsequent cell process. When the protective layer is removed during the process, if the adhesion strength between the protective layer 450 and the protective layer is high, damage due to panel delamination may occur when the protective layer is removed. In this case, a display driving defect due to the panel delamination may occur when driving the display device later. Therefore, it is desired that the adhesion strength of the third portion A3 and the fifth portion A5 to the protective layer is relatively lower than other parts. The adhesion strength of the third portion A3 and the fifth portion A5 with the protective layer attached during the process may be reduced by applying a relatively lower exposure energy compared to other parts of the protective layer 450.

The first portion A1, the second portion A2, and the fourth portion A4 may be formed by applying a higher exposure energy compared to the third portion A3 and the fifth portion A5. As the exposure energy increases, the thickness of the layer increases, so the thickness d1 of the first portion A1, the thickness d2 of the second portion A2, and the thickness d4 of the fourth portion A4 may be greater than the thickness d3 of the third portion A3. The thickness d5 of the fifth portion A5 may be smaller than the thickness d1 of the first portion A1, the thickness d2 of the second portion A2, and the thickness d4 of the fourth portion A4. At least one of the difference between the thickness d4 of the fourth portion A4 and the thickness d3 of the third portion A3, and the difference between the thickness d4 of the fourth portion A4 and the thickness d5 of the fifth portion A5 may be 1,000 Å or more (e.g., 1,000 Å to 5,000 Å).

The first portion A1, the second portion A2, and the fourth portion A4 may be formed with a higher exposure energy compared to the third portion A3 and the fifth portion A5. As the exposure energy increases, the adhesion strength to the upper layer increases. The adhesion strength of the first portion A1, the second portion A2, and the fourth portion A4 may be greater than the adhesion strength of the third portion A3 and the fifth portion A5. The adhesion strength of the third portion A3 and the fifth portion A5 may be smaller than the adhesion strength of the first portion A1, the second portion A2, and the fourth portion A4.

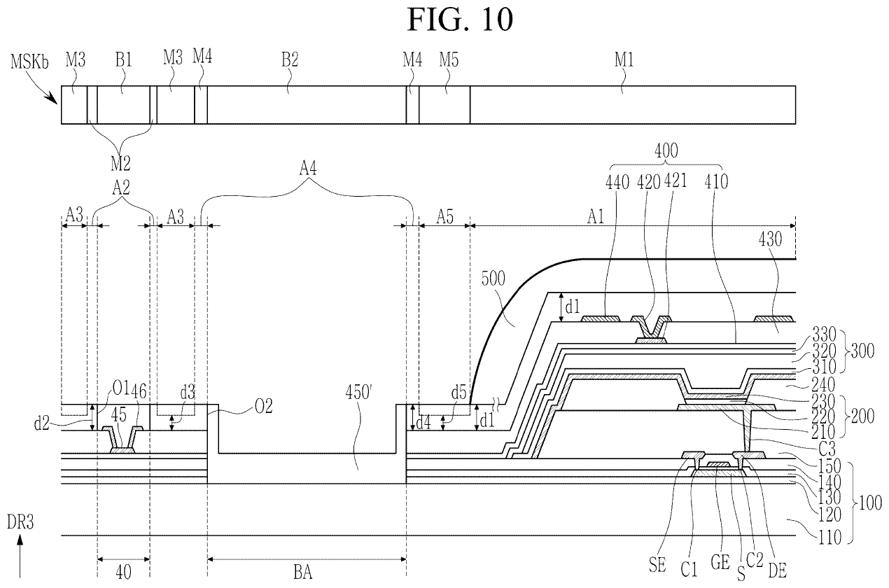

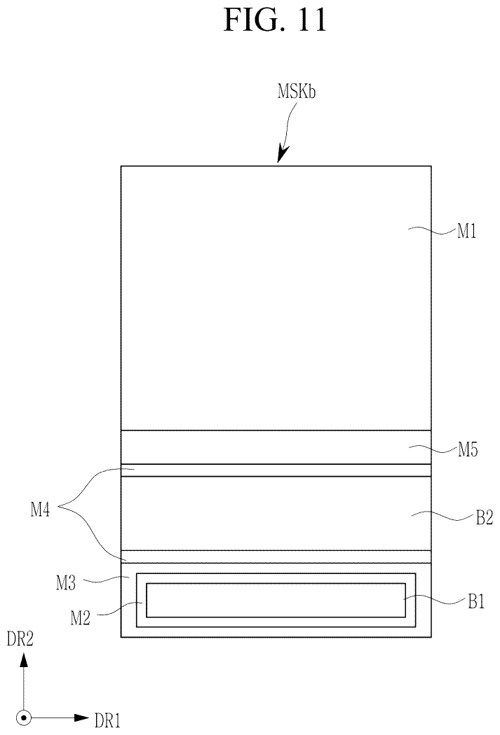

FIG. 10 is a cross-sectional view showing a method for manufacturing a display device according to some example embodiments, and FIG. 11 is a schematic plan view of a photomask according to some example embodiments, showing a method for forming the protective layer of the display device according to some example embodiments as shown in FIG. 9. Hereinafter, a method for manufacturing a display device according to some example embodiments will be described with reference to FIGS. 10 and 11.

According to FIG. 10, a pad portion 40 is formed on the upper surface of the peripheral area NA of the substrate. The peripheral area NA of a display device according to some example embodiments may further include a bending area BA. An emission layer 220 and sensing electrodes 420, 440 are formed above the display area DA of the substrate. A protective material layer 450′ is applied above the sensing electrodes 420, 440. The photomask MSKb is positioned above the protective material layer 450′ and light is irradiated through the photomask MSKb. The exposing step may include photo-curing the protective material layer 450′ using ultraviolet light as a light source. After the exposure, the protective material layer 450′ is developed to form a protective layer 450. After the step of forming the protective layer 450, the step may further include forming a planarization layer 500 above the protective layer 450. The step of forming the planarization layer 500 may include inkjet printing a monomer.

According to FIGS. 10 and 11, the photomask MSKb may include a first light-blocking portion B1 overlapping the pad portion, a first light-transmitting portion M1 overlapping the display area, a second light-transmitting portion M2 disposed surrounding the first light-blocking portion B1, and a third light-transmitting portion M3 disposed surrounding the second light-transmitting portion M2. When a display device according to some example embodiments includes a bending area BA, the photomask MSKb may further include a second light-blocking portion B2 overlapping the bending area BA. Also, the photomask MSKb may further include a fourth light-transmitting portion M4 having portions on opposite sides of the second light-blocking portion B2, and may further include a fifth light-transmitting portion M5 disposed between the first light-transmitting portion M1 and the fourth light-transmitting portion M4.

The light transmittance in the first light-transmitting portion M1, the second light-transmitting portion M2, and the fourth light-transmitting portion M4 may be 90% or more (e.g., 90% to 99.9%). The first light-transmitting portion M1 and the second light-transmitting portion M2 may be full-tone masks where 90% or more (e.g., 90% to 99.9%) of light is transmitted. It is desirable the first portion A1 formed by the first light-transmitting portion M1 has higher adhesion strength, and the second portion A2 and the fourth portion A4 formed by the second light-transmitting portion M2 and the fourth light-transmitting portion M4 may be applied by a exposure energy intensity at a certain reference to prevent or reduce the layer lifting phenomenon in the development process, so the light transmittance of the photomask MSKb is high or relatively higher at the first light-transmitting portion M1, the second light-transmitting portion M2, and the fourth light-transmitting portion M4 than the remaining portions of the photomask MSKb.

The light transmittance in the third light-transmitting portion M3 and the fifth light-transmitting portion M5 may be 20% to 70%. The third light-transmitting portion M3 may be a half-tone mask. A protective layer may be attached on the third portion A3 and the fifth portion A5 formed by the third light-transmitting portion M3 and the fifth light-transmitting portion M5, and the protective layer may be removed in the subsequent process. Thus, a relatively lower adhesion strength is desired for the third portion A3 and the fifth portion A5 to prevent or reduce delamination. Therefore, by setting the transmittance of the third light-transmitting portion M3 and the fifth light-transmitting portion M5 to 20% to 70%, the exposure energy applied to the protective material layer 450′ in the parts overlapping the third light-transmitting portion M3 and the fifth light-transmitting portion M5 can be lowered.

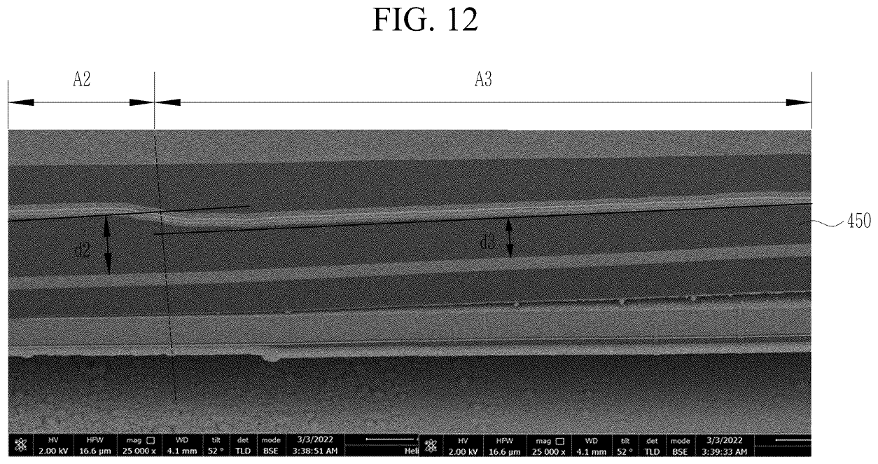

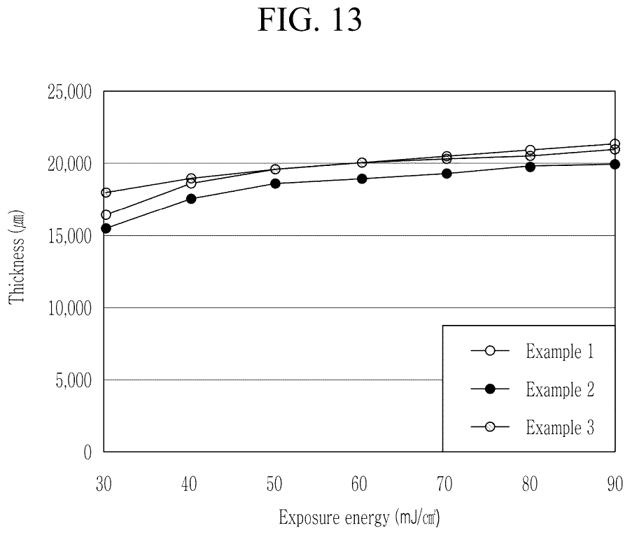

FIG. 12 is a graph showing the thickness of the protective layer 450 according to exposure energy. FIG. 13 is a table showing the thickness of the protective layer 450 according to exposure energy according to some example embodiments. Hereinafter, the change in thickness of the protective layer 450 according to exposure energy will be examined with reference to FIGS. 12 and 13.

In FIG. 12, Examples 1 to 3 correspond to protective layers 450 formed by different types of protective material layers 450′. In the Examples 1 to 3, the material of the protective layer 450 is a negative-type material with the characteristic that the part exposed to light remains after development. Referring to the graphs in FIG. 12, in all Examples 1 to 3, as the exposure energy increases, the remaining film rate is increased, and as a result the thickness of the layer also increases.

According to FIG. 13, in all Examples 1 to 3, the initial thickness of the protective material layer 450′ before light exposure is 23000 Å. For all Examples 1 to 3, the sensitivity of the protective material layer 450′ is constant or substantially constant, for example as 50 mJ/cm2. Here, the sensitivity refers to the exposure energy required per unit area, and means the minimum amount of light required for the photosensitive material layer to form the desired pattern. It can be seen that the protective material layers 450′ of Examples 1 to 3 are cured to the same degree when given the same amount of light.

In Example 1, when the exposure energy is 30 mJ/cm2, the thickness of the protective layer 450 is formed as 16500 Å. When the exposure energy is 40 mJ/cm2, the thickness of the protective layer 450 is formed as 18800 Å. When the exposure energy is 50 mJ/cm2, the thickness of the protective layer 450 is formed as 19700 Å, and when the exposure energy is 60 mJ/cm2, the thickness of the protective layer 450 is formed as 20200 Å. When the exposure energy is 70 mJ/cm2, the thickness of the protective layer 450 is 20600 Å, when the exposure energy is 80 mJ/cm2, the thickness of the protective layer 450 is 21000 Å, and when the exposure energy is 90 mJ/cm2, the thickness of the protective layer 450 is 21400 Å. When the exposure energy is 50 mJ/cm2, the remaining film rate of the protective material layer 450′ is about 86%.

In Example 2, when the exposure energy is 30 mJ/cm2, the thickness of the protective layer 450 is formed as 15600 Å. When the exposure energy is 40 mJ/cm2, the thickness of the protective layer 450 is formed as 17700 Å. When the exposure energy is 50 mJ/cm2, the thickness of the protective layer 450 is formed as 18700 Å, and when the exposure energy is 60 mJ/cm2, the thickness of the protective layer 450 is formed as 19100 Å. When the exposure energy is 70 mJ/cm2, the thickness of the protective layer 450 is 19500 Å, when the exposure energy is 80 mJ/cm2, the thickness of the protective layer 450 is 19900 Å, and when the exposure energy is 90 mJ/cm2, the thickness of the protective layer 450 is 20000 Å. When the exposure energy is 50 mJ/cm2, the remaining film rate of the protective

In Example 3, when the exposure energy is 30 mJ/cm2, the thickness of the protective layer 450 is formed as 18200 Å. When the exposure energy is 40 mJ/cm2, the thickness of the protective layer 450 is formed as 19100 Å. When the exposure energy is 50 mJ/cm2, the thickness of the protective layer 450 is formed as 19800 Å, and when the exposure energy is 60 mJ/cm2, the thickness of the protective layer 450 is formed as 20200 Å. When the exposure energy is 70 mJ/cm2, the thickness of the protective layer 450 is 20500 Å, when the exposure energy is 80 mJ/cm2, the thickness of the protective layer 450 is 20800 Å, and when the exposure energy is 90 mJ/cm2, the thickness of the protective layer 450 is 21200 Å. When the exposure energy is 50 mJ/cm2, the remaining film rate of the protective material layer 450′ is about 86%.

According to the change in the remaining layer thickness according to exposure energy in FIGS. 12 and 13, when the thickness of the protective layer 450 differs by 1000 Å or more (e.g., 1,000 Å to 5,000 Å) by part, it can be known that a change in exposure energy of 10 mJ or more (e.g., 10 mJ to 50 mJ) was given using a photomask with different transmittance by part.

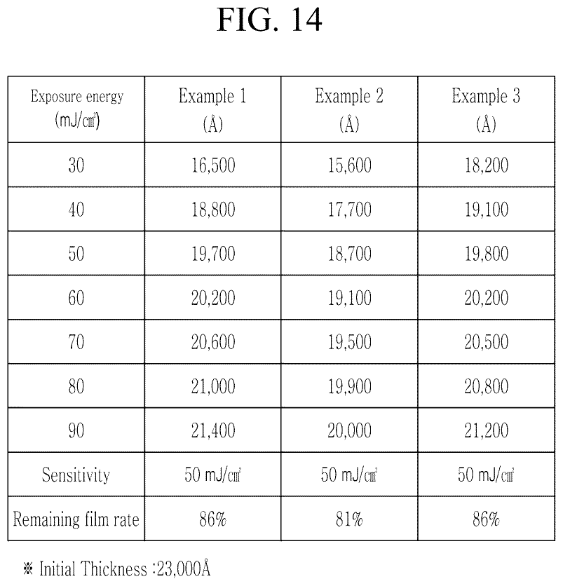

FIG. 14 is a table showing the thickness of a protective layer according to exposure energy according to some example embodiments.

Referring to FIG. 14 together with FIGS. 6 and 10, when light exposed through the second light-transmitting portion M2 of the photomask is applied to the protective material layer 450′, the second portion A2 of the protective layer 450 may be formed. When light exposed through the third light-transmitting portion M3 of the photomask MSKa, MSKb is applied to the protective material layer 450′, the third portion A3 of the protective layer 450 may be formed. The light transmittance in the second light-transmitting portion M2 may be 90% or more (e.g., 90% to 99.9%), and the light transmittance in the third light-transmitting portion M3 may be 20% to 70%. Therefore, there may be a difference in layer thickness due to the difference in exposure energy. The thickness at the second portion A2, which is the part exposed to a higher exposure energy, is greater than the thickness at the third portion A3, and the difference between the thickness of the second portion A2 and the thickness of the third portion A3 is 1000 Å or more (e.g., 1,000 Å to 5,000 Å). Since the thickness difference is 1000 Å or more (e.g., 1,000 Å to 5,000 Å), it can be seen that there was a difference of 10 mJ or more (e.g., 10 mJ to 50 mJ) in the exposure energy during the photolithography process.

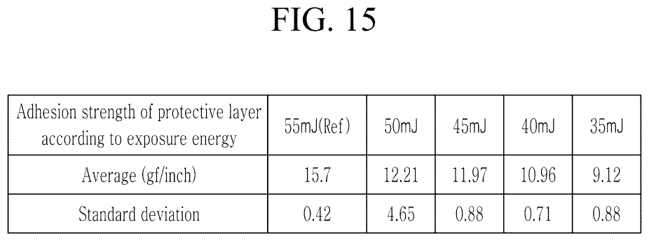

FIG. 15 is a table showing the adhesion strength of a protective layer to a protective layer according to exposure energy according to some example embodiments.

When the exposure energy is 55 mJ, the average adhesion strength of the protective layer 450 to the protective layer corresponds to 15.7 gf/inch. At this time, the standard deviation is 0.42.

When the exposure energy is 50 mJ, the average adhesion strength of the protective layer 450 to the protective layer corresponds to 12.21 gf/inch. At this time, the standard deviation is 4.65.

When the exposure energy is 45 mJ, the average adhesion strength of the protective layer 450 to the protective layer corresponds to 11.97 gf/inch. At this time, the standard deviation is 0.88.

When the exposure energy is 40 mJ, the average adhesion strength of the protective layer 450 to the protective layer corresponds to 10.96 gf/inch. At this time, the standard deviation is 0.71.

When the exposure energy is 35 mJ, the average adhesion strength of the protective layer 450 to the protective layer corresponds to 9.21 gf/inch. At this time, the standard deviation is 0.88.

It can be seen that the larger the exposure energy, the greater the adhesion strength of the protective layer 450 to the upper layer. Therefore, by applying a relatively higher exposure energy to an area where higher adhesion strength is desired, and applying a relatively lower exposure energy to an area where lower adhesion strength is desired, different adhesion strengths by position can be satisfied simultaneously. At the same time, by applying a relatively higher exposure energy, the lifting phenomenon of the protective layer 450 that may occur during the development process at the pattern boundary can be prevented or reduced.

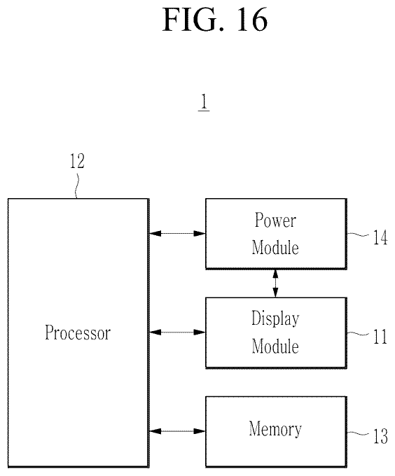

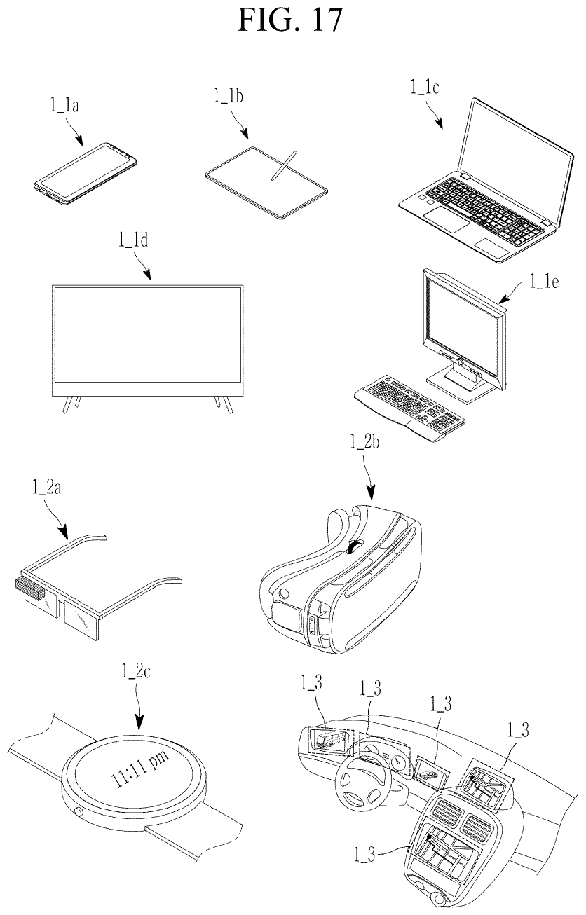

Hereinafter, an electronic device to which the display device according to some example embodiments can be applied will be examined with reference to FIGS. 16 and 17. FIG. 16 is a block diagram of an electronic device according to some example embodiments, and FIG. 17 is a set of schematic diagrams of electronic devices according to various example embodiments.

The above embodiments may be applied to various electronic devices 1. An electronic device 1 according to some example embodiments may include the display device 30 of FIG. 1, and may further include a module or a device having other additional functions besides the display device 30 of FIG. 1.

FIG. 16 is a block diagram of an electronic device 1 according to some example embodiments. Referring to FIG. 16, an electronic device 1 according to some example embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, image data signals and/or input control signals are transferred to the display module 11, and the display module 11 processes the provided signals to output image information through the display screen.

The power module 14 may include a power supply module such as a power adapter or a battery device, and a power conversion module that converts the power supplied by the power supply module to generate the power necessary for the operation of the electronic device 1.

At least one of the components of the electronic device 1 described above may be included in the display device according to some example embodiments described above. Also, some of the individual modules included in one module functionally may be included in the display device, and others may be provided separately from the display device. For example, the display device 30 of FIG. 1 may include the display module 11, and the processor 12, memory 13, and power module 14 may be provided in the form of other devices within the electronic device 1 rather than the display device.

FIG. 17 are schematic diagrams of electronic devices according to various example embodiments.

Referring to FIG. 17, various electronic devices to which the display device according to some example embodiments is applied may include not only image display electronic devices such as a smartphone 1_1a, a tablet PC 1_1b, a laptop 1_1c, a TV 1_1d, a desktop monitor 1_1e, and/or the like, but also wearable electronic devices including a display module, such as smart glasses 1_2a, a head-mounted display 1_2b, a smart watch 1_2c, and/or the like, and vehicle electronic devices 1_3 including a display module, such as a dashboard, a center fascia, a Center Information Display (CID) arranged on a dashboard, a room mirror display, and/or the like of a car.

When the terms “about” or “substantially” are used in this specification in connection with a numerical value, it is intended that the associated numerical value includes a manufacturing or operational tolerance (e.g., ±10 %) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing, measuring, and/or operational tolerance (e.g., ±10 %) around the stated numerical values or shapes.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B. While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Although some example embodiments of the present inventions have been described in detail above, the scope of rights of the present inventions are not limited to this, and various modifications and improvements by those skilled in the art using the basic concept of the present inventions defined in the following claims also fall within the scope of rights of the present inventions.

What is claimed is:

1. A display device, comprising:
a substrate including a display area and a peripheral area adjacent to the display area;
an emission layer above the display area;
a pad portion on an upper surface of the peripheral area;
a sensing layer above the emission layer;
a protective layer above the sensing layer; and
a planarization layer above the protective layer,
the sensing layer including a sensing electrode,
the protective layer comprising a first portion overlapping the planarization layer, a second portion, and a third portion overlapping the peripheral area,
the protective layer having a first opening in the peripheral area and overlapping the pad portion, the second portion surrounding a periphery of the first opening, and the third portion including a portion surrounding a periphery of the second portion, and
a thickness of the third portion being smaller than a thickness of the first portion and a thickness of the second portion.

2. The display device of claim 1,
wherein a difference between the thickness of the third portion and the thickness of each of the first portion and the second portion is 1,000 Å to 5,000 Å.

3. The display device of claim 2,
wherein an adhesion strength of the first portion is greater than an adhesion strength of the third portion.

4. The display device of claim 3,
wherein an adhesion strength of the second portion is greater than the adhesion strength of the third portion.

5. The display device of claim 4,
wherein the peripheral area further comprises a bending area.

6. The display device of claim 5,
wherein the protective layer further has a second opening overlapping the bending area.

7. The display device of claim 6,
wherein the protective layer further comprises a fourth portion including portions on opposite sides of the second opening, and a thickness of the fourth portion is greater than the thickness of the third portion.

8. The display device of claim 7,
wherein the protective layer further comprises a fifth portion between the first portion and the fourth portion, and a thickness of the fifth portion is smaller than the thickness of the first portion and the thickness of the fourth portion.

9. The display device of claim 8,
wherein at least one of a difference between the thickness of the fourth portion and the thickness of the third portion, or a difference between the thickness of the fourth portion and the thickness of the fifth portion is 1,000 Å to 5,000 Å.

10. The display device of claim 9,
wherein an adhesion strength of the fifth portion is lower than the adhesion strength of the first portion.

11. The display device of claim 9,
wherein an adhesion strength of the fourth portion is greater than the adhesion strength of the third portion and an adhesion strength of the fifth portion.

12. A method for manufacturing a display device, the method comprising:
forming a pad portion on an upper surface of a peripheral area of a substrate;
forming an emission layer and a sensing electrode above a display area of the substrate;
applying a protective material layer above the sensing electrode;
positioning a photomask above the protective material layer and irradiating light through the photomask;
developing the protective material layer to form a protective layer; and
forming a planarization layer above the protective layer,
the photomask including
a first light-blocking portion overlapping the pad portion,
a first light-transmitting portion overlapping the planarization layer,
a second light-transmitting portion surrounding the first light-blocking portion, and
a third light-transmitting portion surrounding the second light-transmitting portion, and
a light transmittance in the first light-transmitting portion and the second light-transmitting portion being 90% to 99.9%.

13. The method for manufacturing the display device of claim 12,
wherein a light transmittance in the third light-transmitting portion is 20% to 70%.

14. The method for manufacturing the display device of claim 13,
wherein the peripheral area further comprises a bending area.

15. The method for manufacturing the display device of claim 14,
wherein the photomask further includes a second light-blocking portion overlapping the bending area.

16. The method for manufacturing the display device of claim 15,
wherein the photomask further includes a fourth light-transmitting portion including portions on opposite sides of the second light-blocking portion, and a light transmittance in the fourth light-transmitting portion is 90% to 99.9%.

17. The method for manufacturing the display device of claim 16,
wherein the photomask further includes a fifth light-transmitting portion between the first light-transmitting portion and the fourth light-transmitting portion, and a light transmittance in the fifth light-transmitting portion is 20% to 70%.

18. The method for manufacturing the display device of claim 13,
wherein the forming the planarization layer comprises inkjet printing a monomer.

19. The method for manufacturing the display device of claim 13,
wherein the irradiating light comprises photo-curing the protective material layer using ultraviolet light as a light source.

20. An electronic device, comprising:
a display module; and
a processor connected to the display module,
the display module comprising
a substrate including a display area and a peripheral area adjacent to the display area;
an emission layer above the display area;
a pad portion disposed on an upper surface of the peripheral area;
a sensing layer above the emission layer;
a protective layer above the sensing layer; and
a planarization layer above the protective layer,
the sensing layer including a sensing electrode,
the protective layer comprising a first portion overlapping the planarization layer, a second portion, and a third portion overlapping the peripheral area,
the protective layer having a first opening in the peripheral area and overlapping the pad portion, the second portion surrounds a periphery of the first opening, and the third portion includes a portion surrounding a periphery of the second portion, and
a thickness of the third portion being smaller than a thickness of the first portion and a thickness of the second portion.
